(19) United States
(12) Patent Application Publication
(10) Pub. No.: US 2008/0297378 A1
(43) Pub. Date: Dec. 4, 2008

(54) NUMERAL INPUT METHOD

(76) Inventor: Wei-Chou SU, Tainan City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/755,741

(22) Filed: May 31, 2007

(51) Int. Cl. H03M 11/00

(52) U.S. Cl. 341/23

(57) ABSTRACT

A numeral input method simply uses the keys of a mobile phone or some of a computer keyboard and the beginning point and the ending point of each English letter manually written by hand on the keys to achieve a numeral code system for the English alphabet. So, under the mode, Chinese characters and English alphabets (small and capital letters), numerals and simple symbols can be retrieved, even available for other languages. It can lessen the knocking times on the keys and make input operated easily and conveniently like writing on a mobile phone or a keyboard, an people all over the world speaking diverse languages can key in sentences, information, etc. more easily and quickly.

### BACKGROUND OF THE INVENTION

1. Field of the Invention

This invention relates to a numeral input method, particularly to one enabling the English letters formatted as numeral codes by means of the numeral and symbol keys of a mobile phone or a computer keyboard. So, any language other than those spelt by the English alphabet can be transliterated with English letters so as to accordingly establish numeral codes that can be easily memorized and keyed in quickly and conveniently.

2. Description of the Prior Art

Nowadays, each key of a mobile phone is designed to diversely represent numerals (0˜9), alphabets (ABC . . . ), Chinese phonetic symbols ( [symbol] . . . ), and other symbols, not only making the keys look complicated, but also needing to shift and knock the keys manifoldly to retrieve a character wanted. Moreover, the input methods for Chinese characters, such as the phonetic symbol coding scheme and the Tsangjei coding scheme etc., have very complicated regulations for exploding words, not only uneasy for a user to memorize the regulations, but also making a keyboard look too sophisticated. And, as for Chinese transliteration, there are plural versions used, such as Roman phonetics and Taiwan Tongyong phonetics etc., easy to be confused because of a lack of consistency.

### SUMMARY OF THE INVENTION

The objective of this invention is to offer a numeral input method that is apt to be memorized and keyed in swiftly and handily.

The present invention uses only the numeral and the symbol keys of a mobile phone to achieve numeral codes for characters, with procedures described below.

First, languages are transliterated with the English letters. Next, find a beginning point and an ending point of each letter written by hand on twelve keys represented by numerals and symbols of a mobile phone. The numeral keys of the beginning point and the ending point are used as the basis for achieving a numeral code for the letter.

The numeral code is displayed as a small letter if keyed in without repeated numeral.

The numeral code is displayed as a capital letter if its unit is keyed in twice.

If a key is successively knocked thrice, the numeral or the symbol of the key is to be displayed.

The “0” key is set as a space bar.

The twelve keys can be randomly set at any inputting device in accordance to a user's habit.

The [symbol] key of a mobile phone is established as a language shift key.

The Chinese phonetic notations are transliterated with English letters and then, encoded with the numeral codes accordingly.

The “0” key of a mobile phone or the space bar of a computer keyboard represents tone 1 for Chinese pronunciation; the [symbol] key of the mobile phone or the “2” key of the computer keyboard represents tone 2; the “>” key of the mobile phone or the “3” key of the computer keyboard represents tone 3; the [symbol] key of the mobile phone or the “4” key of the computer keyboard represents tone 4; and the “<” key of the mobile phone or the “5” key of the computer keyboard represents light tone.

The pronunciation can be heard while keying in a numeral code and a whole sentence can be heard after knocking on the “•” key, helpful for the handicapped to use.

The Chinese phonetic notations are transliterated with English alphabets and then, formatted with the numeral codes that are coded as simply as can be, without any one repeated.

As for those Chinese phonetic notations transliterated with more than one letter, their numeral codes are made up by taking the first numeral of the first letter and the last numeral of the last letter.

### BRIEF DESCRIPTION OF DRAWINGS

This invention is better understood by referring to the accompanying drawings, wherein:

FIG. 1 is a diagram of the numeral and the function keys of a conventional mobile phone;

FIG. 2 is a diagram of the preferred embodiment of a numeral input method in the present invention, showing a beginning and an ending point of small letters written by hand on the numeral keys of the conventional mobile phone;

FIG. 3 is a diagram of the preferred embodiment of a numeral input method in the present invention, showing the letters coded with a single numeral of the conventional mobile phone;

FIG. 4 is a table of the preferred embodiment of a numeral input method in the present invention, showing the numeral codes for capital letters, small letters and symbols commonly used;

FIG. 5 is a table of the preferred embodiment of a numeral input method in the present invention, showing the numeral codes for numerals (0˜9) and symbols (* and #);

FIG. 6 is a table of the preferred embodiment of a numeral input method in the present invention, showing transliteration for Chinese phonetic symbols and their numeral codes; and

FIG. 7 is a table of the preferred embodiment of a numeral input method in the present invention, showing examples of some languages and their numeral codes.

### DETAILED DESCRIPTION OF THE PREFERRED EMBODIMENT

A preferred embodiment of a numeral input method in the present invention is described below.

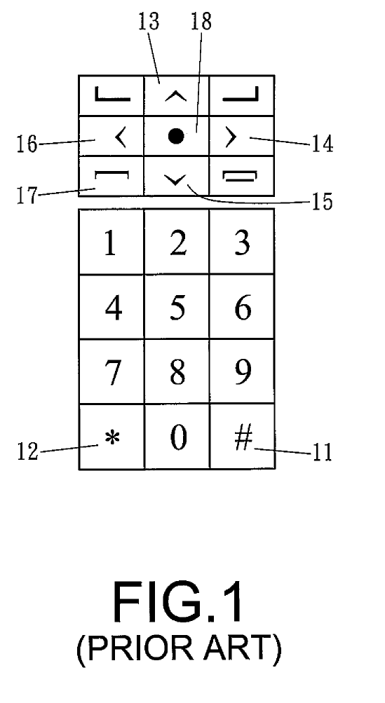

All kinds of languages are transliterated with English letters that are respectively coded with numerals, “0˜9”, “#”, representing “11” and “*” representing “12” as those labeled on the keys of a mobile phone, as shown in FIG. 1.

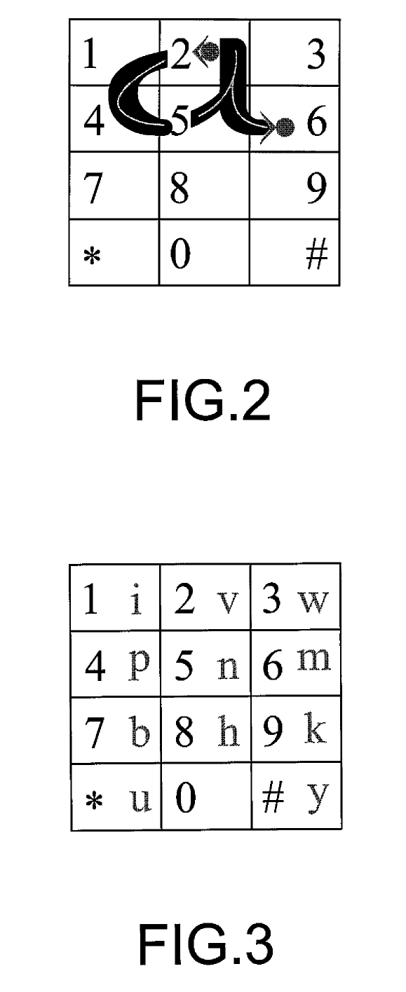

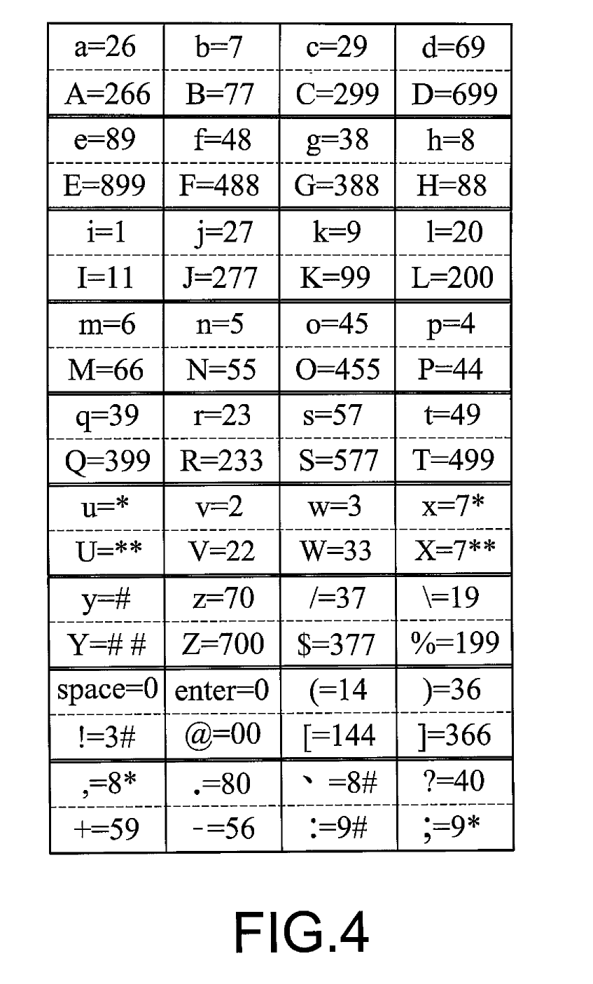

As shown in FIG. 2, the basic concept of encoding the present invention is to imagine each small letter is written on twelve keys of numerals and symbols of a mobile phone, having a beginning point and an ending point against corresponding keys. For example, “a” is written via beginning from the key of “2” and ending at that of “6”, thus its numeral code is 26. When 2 and 6 are successively keyed in, the letter “a” is displayed on a mobile phone. If a letter has its beginning point located at numeral “1”, it is only coded with the numeral of its ending point without “1”. Such as “b”, it begins at numeral “1” and ends at numeral “7”, thus a single “7” represents “b”. Accordingly, FIG. 3 shows the letters represented by a single numeral and FIG. 4 shows the numeral codes of the rest of the letters and the symbols. Instead of the mobile phone, the twelve keys can be set at random locations of other input devices in accordance with a user's habit. For example, the keys of 7, 8, 9, U, I, O, J, K, L, M, < and > in a notebook computer may be used as those used in the mobile phone.

When a capital letter is wanted, the unit of its numeral code must be keyed in twice, as shown in FIG. 4. For example, the numeral code of “a” is 26 having a unit of “6”, thus capital A is encoded as 266.

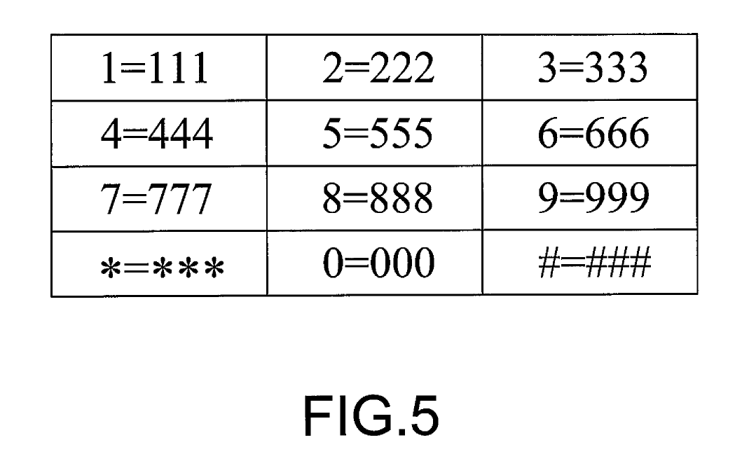

As shown in FIG. 5, when a numeral or a symbol key is successively keyed in thrice, the numeral or the symbol of itself can be obtained.

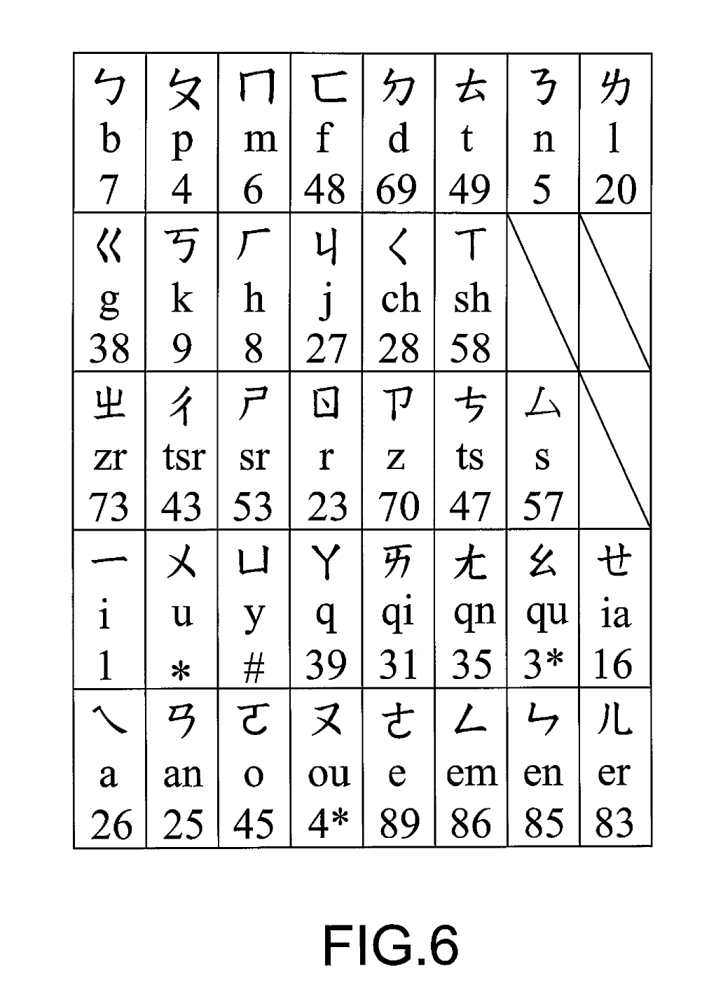

For Chinese pronunciation, some keys of a mobile phone and those of a computer keyboard are established to represent tone 1, tone 2, tone 3, tone 4 and light tone. As shown in FIG. 1, the “0” key of a mobile phone or the space bar of a computer keyboard is to represent tone 1; the [symbol] key (13) of a mobile phone or the “2” key of a computer keyboard is to represent tone 2; the “>” key (14) of a mobile phone or the “3” key of a computer keyboard is to represent tone 3; the [symbol] key (15) of a mobile phone or the “4” key of a computer keyboard is to represent tone 4; and the “<” key (16) of a mobile phone or the “5” key of a computer keyboard is to represent light tone. With the input to distinguish different pronouncing tones, characters retrieved can be minimized to let a user easily find what is wanted therein. And, Chinese characters can be transliterated with English letters, which can thus be coded with the numeral codes so as to retrieve Chinese characters, as shown in FIG. 6.

In addition, as shown in FIG. 1, the [symbol] key (17) of a mobile phone can be set as a shift key for changing languages, and “0” key can function as a space bar for separating characters. Or, the other keys may be selected to replace the keys mentioned above, for the sake of practical operation. Therefore, Chinese, English, symbols and numerals can be simultaneously inputted by means of the present invention.

In order to be helpful to the handicapped, the present invention can be combined with sound so that it can pronounce while keying in and speak out a whole sentence after knocking on the “•” key, as shown in FIG. 1.

FIG. 6 is a table showing alphabetic transliteration of Chinese phonetic symbols and their numeral codes, which are basically formatted as simply as can be, with no one repeated. For example, [symbol] is transliterated as ┌b┘ and coded with ┌7┘; [symbol] is transliterated as ┌f┘ and coded with ┌48┘. When a phonetic symbol is transliterated with more than one letter, its numeral code is a combination of the first numeral of the numeral code of the first letter and the last numeral of the last numeral code of the last letter. For example, the phonetic symbol of [symbol] is transliterated with ┌er┘, thus its numeral code is ┌83┘ as 8 is the first numeral of the numeral code of “e” and 3 is the last numeral of the numeral code of “e”; the phonetic symbol of [symbol] is transliterated with ┌tsr┘, thus its numeral code is ┌43┘ as 4 is the first numeral of the numeral code of “t” and 3 is the last numeral of the numeral code of “r” with “s” lined between “t” and “r” ignored; the phonetic symbol of [symbol] is transliterated with ┌qn┘, thus its numeral code is ┌35┘ as 3 is the first numeral of the numeral code of “q” and 5 is the single numeral of the numeral code of “n”; the phonetic symbol of [symbol] is transliterated with ┌qu┘, thus its numeral code is ┌3*┘ as 3 is the first numeral of the numeral code of “q” and * represents “u”; and, the rest of the phonetic symbols are coded alike as listed in FIG. 6. So, if a mobile phone or a computer has no Chinese input method, the alphabet or the numeral code can be used alternately.

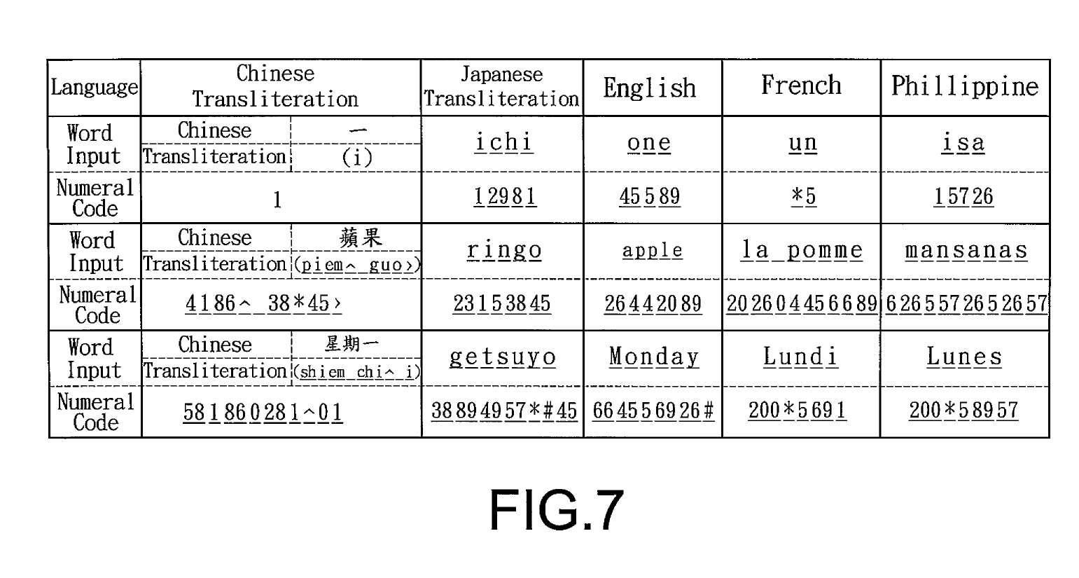

Languages spoken all over the world can be retrieved by the numeral input method in the present invention as long as they are transliterated in accordance with regulated rules or modes, as shown in FIG. 7. For example, it needs to knock 30 times on the keys of the conventional mobile phone to get an English phrase of “Good morning!” but merely 22 times by the numeral input method of the present invention without having to focus hard on the screen to look for characters; for Chinese phrase [symbol] [symbol] a user has to knock 15 times on the keys of the conventional mobile phone by inputting phonetic symbol but merely 11 times by the numeral input method of the present invention via transliterating [symbol] into “tsqu > an”; as for Japanese “ohayo!” (Good morning!), it can be coded with “45826#453#”. In the future, some functions such as characters commonly used or phrases optioned by users themselves may be added in the present invention to effectively lessen the knocking times.

The invention has the following advantages as can be seen from the foresaid description.

1. The numeral input method of the present invention is used like writing by a hand, easy to memorize the regulations and convenient for the handicapped to use as one finger can make it.

2. The numeral input method of the present invention can lessen knocking times on the keys and, combined with pronunciation, a user does not have to focus hard on the screen to look for characters. A numeral keyboard can effectively replace a computer keyboard, possible to provide a cuffing-edge innovation.

3. Via the combination with the numeral codes of the English letters, Chinese transliteration makes the features of Chinese phonetic notation completely presented as it is able to precisely pronounce to make it easily understood and prevent it from being confused.

4. Combining Chinese transliteration with the numeral input method of the present invention can make an integration for a computer and a mobile phone to simplify the keys.

While the preferred embodiment of the invention has been described above, it will be recognized and understood that various modifications may be made therein and the appended claims are intended to cover all such modifications that may fall within the spirit and scope of the invention.

What is claimed is:

1. A numeral input method using only numerals and symbols to code characters, said method comprising:
a first step of transliterating languages with the English letters, finding a beginning point and an ending point of each letter manually written on twelve keys of numerals and symbols of a mobile phone, the numeral keys of said beginning point and said ending point used as a basis to achieve a numeral code for said letter;
a second step of displaying said numeral code as a small letter if keyed in only once;
a third step of displaying said numeral code as a capital letter if said numeral code is keyed in twice; and
a fourth step of displaying the numeral or the symbol of a key if said key is knocked thrice, with a key “0” set as a space bar.

2. The numeral input method as claimed in claim 1, wherein said twelve keys are randomly set in any inputting device in accordance to a user's habit.

3. The numeral input method as claimed in claim 1, wherein a [symbol] key of a mobile phone is established as a language shift key.

4. The numeral input method as claimed in claim 1, wherein Chinese phonetic symbols are transliterated with said English alphabets and then, encoded with numeral codes of said English alphabets accordingly.

5. The numeral input method as claimed in claim 1, wherein the “0” key of a mobile phone or a space bar of a computer keyboard represents tone 1 for Chinese pronunciation, a [symbol] key of a mobile phone or a “2” key of a computer keyboard represents tone 2; a “>” key of a mobile phone or a “3” key of a computer keyboard represents tone 3; a [symbol] key of a mobile phone or a “4” key of a computer keyboard represents tone 4; and a “<” key of a mobile phone or a “5” key of a computer keyboard represents light tone.

6. The numeral input method as claimed in claim 1, wherein pronunciation is heard while keying in and a whole sentence is heard after knocking on a “•” key so as to be helpful for the handicapped to hear, say, read or write.

7. The numeral input method as claimed in claim 1, wherein said Chinese phonetic symbols are transliterated with English alphabets and then, formatted with numeral codes of said English alphabets that can be coded as simply as can be, without any one repeated.

8. The numeral input method as claimed in claim 1, wherein if English alphabets of Chinese phonetic symbols transliterated are more than one letter, they are encoded by taking the first numeral of the first letter and the last numeral of the last letter.
